(19) United States
(12) Patent Application Publication
(10) Pub. No.: US 2014/0233001 A1
(43) Pub. Date: Aug. 21, 2014

(54) APPARATUS AND METHOD FOR PERFORMING MULTI-BEAM BASED LITHOGRAPHY

(71) Applicant: SAMSUNG ELECTRONICS CO., LTD., Suwon-si (KR)

(72) Inventors: JIN CHOI, Yongin-si (KR); Sin-Jeung Park, Gangnam-gu (KR); Young-Su Sung, Chuncheon-si (KR)

(73) Assignee: SAMSUNG ELECTRONICS CO., LTD., Suwon-si (KR)

(21) Appl. No.: 14/169,821

(22) Filed: Jan. 31, 2014

(30) Foreign Application Priority Data
Feb. 19, 2013 (KR) 10-2013-0017580

(51) Int. Cl. G03F 7/20

(52) U.S. Cl. CPC G03F 7/70208
USPC 355/55

(57) ABSTRACT

An apparatus for performing lithography includes a light source that emits light. A light enhancer is configured to receive and enhance the emitted light. The light enhancer includes a first lens and a second lens. A first position adjusting unit is configured to adjust a position of the second lens. A lens array is configured to separate the light enhanced by the light enhancer into multiple beams, and focus the multiple beams.

### CROSS-REFERENCE TO RELATED APPLICATION

This application claims priority to Korean Patent Application No. 10-2013-0017580 filed on Feb. 19, 2013 in the Korean Intellectual Property Office, the disclosure of which is incorporated by reference herein its entirety.

### TECHNICAL FIELD

The present inventive concept relates to an apparatus and method for lithography, more particularly, to an apparatus and method for performing multibeam based lithography.

### DISCUSSION OF THE RELATED ART

A lithography apparatus is used in various industrial fields of manufacturing flat panel displays, circuit boards, integrated circuits, and so on. In lithography, a pattern is formed by radiating light into a photoresist layer coated on a substrate. In response to the recently rising demand for manufacturing semiconductor devices having extremely fine patterns, techniques for lithography processes are being developed. In forming fine patterns on a photomask, a distribution of the fine patterns in the photomask directly affects the patterns on a wafer. Accordingly, the quality of fine patterns formed on the photomask is considered.

### SUMMARY

According an exemplary embodiment of the present inventive concept, an apparatus for lithography is provided. An apparatus for performing lithography includes a light source that emits light. A light enhancer is configured to receive and enhance the emitted light. The light enhancer includes a first lens and a second lens. A first position adjusting unit is configured to adjust a position of the second lens. A lens array is configured to separate the light enhanced by the light enhancer into multiple beams, and focus the multiple beams.

According to an embodiment of the present inventive concept, a method for performing lithography is provided. The method for performing lithography includes emitting light. The emitted light is enhanced. A range in which the light is enhanced is adjusted. The enhanced light is separated into multiple beams. The multiple beams are focused.

According to an embodiment of the present inventive concept, an apparatus is provided. The apparatus includes a light source. A light enhancer is configured to receive and enhance the light emitted by the light source. A lens array is configured to separate the light enhanced by the light enhancer into multiple beams and focus the multiple beams. A projection lens is configured to refract the multiple beams separated through the lens array.

### BRIEF DESCRIPTION OF THE DRAWINGS

The above and other features and aspects of the present inventive concept will become more apparent by describing in detail exemplary embodiments thereof with reference to the attached drawings in which:

FIG. 1 is a schematic diagram illustrating an apparatus for performing lithography according to an embodiment of the present inventive concept;

FIG. 2 is a diagram for explaining a tailor-process based method for performing lithography;

FIG. 3 is a diagram for explaining a method for performing lithography according to an embodiment of the present inventive concept;

FIG. 4 is a partially exploded view of the lithography apparatus shown in FIG. 1;

FIGS. 5 and 6 are partially exploded views of an apparatus for performing lithography according to an embodiment of the present inventive concept;

FIG. 7 is a partially exploded view of an apparatus for performing lithography according to an embodiment of the present inventive concept;

FIG. 8 is a flowchart illustrating a method for performing lithography according to an embodiment of the present inventive concept;

FIG. 9 is a flowchart illustrating a method for performing lithography according to an embodiment of the present inventive concept;

FIG. 10 is a flowchart illustrating a method for performing lithography according to an embodiment of the present inventive concept;

FIG. 11 is a block diagram of an electronic system including a semiconductor device fabricated using a lithography apparatus according to an embodiment of the present inventive concept; and

FIGS. 12 and 13 illustrate exemplary systems to which semiconductor devices fabricated using a lithography apparatus according to an embodiment of the present inventive concept may be employed.

### DETAILED DESCRIPTION OF THE EMBODIMENTS

Examplary embodiment of the inventive concept will hereafter be described with reference to the accompanying drawing. However, this inventive concept may be embodied in different forms and should not be construed as limited to the embodiments set forth herein. The same reference numbers may indicate the same components throughout the specification and drawings. In the drawings, the thickness of layers and regions may be exaggerated for clarity.

It will also be understood that when a layer is referred to as being “on” another layer or substrate, it may be directly on the other layer or substrate, or intervening layers may also be present.

As used herein, the singular forms, “a”, “an” and “the” are intended to include both the singular and the plural forms, unless otherwise indicated herein or clearly contradicted by context.

Examplary embodiment of the present inventive concept will be described here with reference to perspective views, cross-sectional views, and/or plan views. Thus, the profile of an exemplary view may be modified according to manufacturing techniques and/or allowances. The embodiments of the inventive concept are not intended to limit the scope of the present invention but are intended to cover all changes and modifications that can be caused due to a change in manufacturing process. Thus, regions shown in the drawings may be illustrated in schematic form and the shapes of the regions may be presented simply by way of illustration.

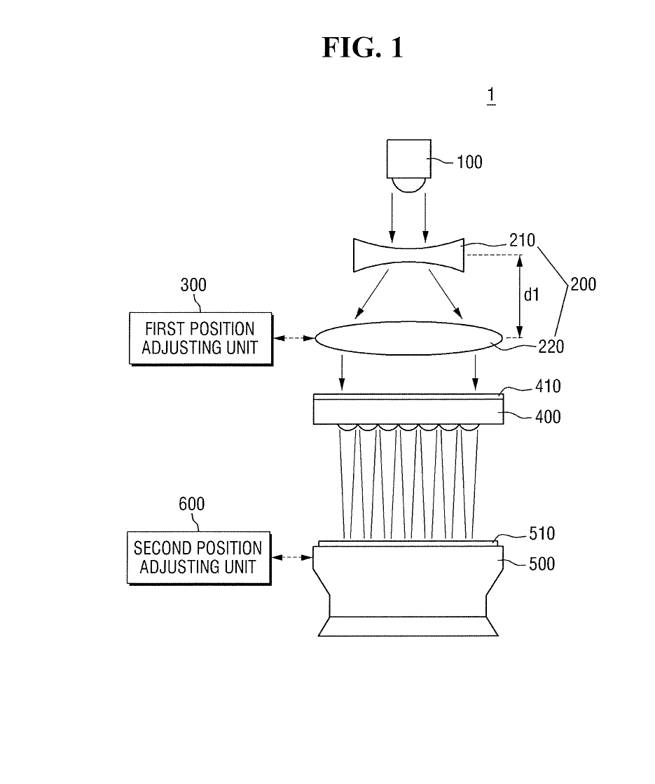

Hereinafter, an apparatus for lithography according to an embodiment of the present inventive concept will be described with reference to FIGS. 1 to 4.

The apparatus and method for lithography, which will be described below, are directed to multibeam-based lithography apparatus and method, which can simultaneously generate a plurality of shading elements on a photomask through one-time exposure. The photomask distribution has been controlled by a photomask fabrication process that is a tailored process. The tailored process is a technique for causing a phase change to an element by focusing laser beam into a quartz photomask and correcting a distribution by varying a transmittance ratio according to the photomask position during lithography process. The phase changed element generated by focusing laser beam is referred to as a shading element. The transmittance ratio is adjusted by the density of shading elements. In a tailed process, a single shading element is formed by an exposure step. However, the number of shading elements generated over the entire area of a photomask may exceed 3 billions. Thus, in a case of employing the tailored process, a time taken for an exposure step may exceed 24 hours.

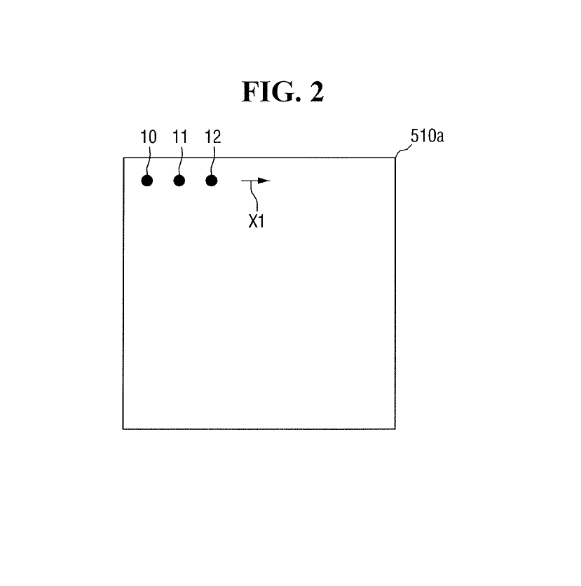

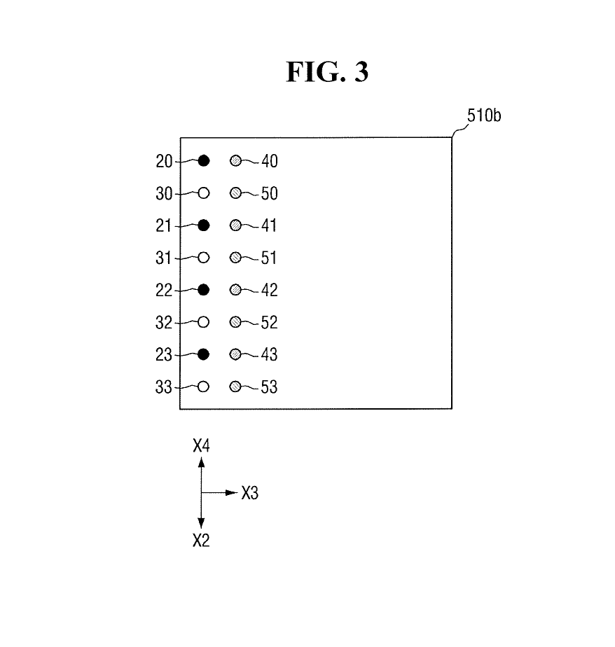

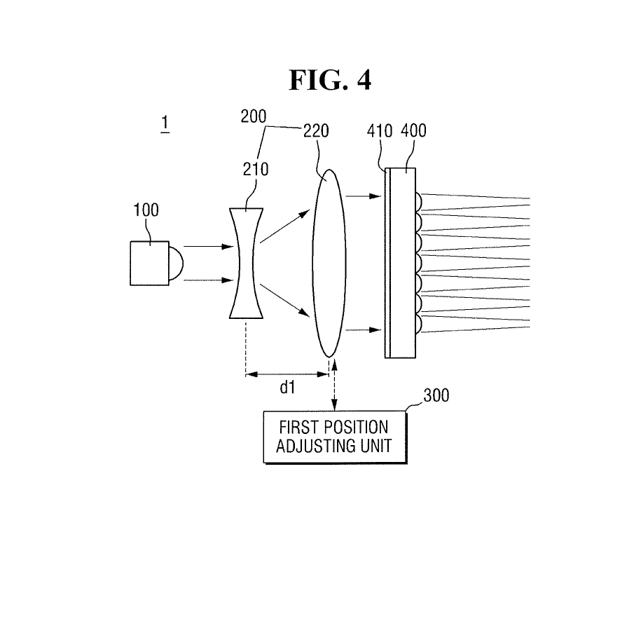

FIG. 1 is a schematic diagram of an apparatus for performing lithography according to an embodiment of the present inventive concept. FIG. 2 is a diagram for explaining a tailor-process based method for performing lithography. FIG. 3 is a diagram for explaining a method for performing lithography according to an embodiment of the present inventive concept. FIG. 4 is a partially exploded view of the lithography apparatus shown in FIG. 1.

Referring to FIGS. 1 and 4, the lithography apparatus 1 includes a light source 100, a light enhancer 200, a first position adjusting unit 300, a lens array 400, and a stage unit 500.

The light source 100 emits light. The light source 100 may be a laser beam light source. In addition to the laser beam light source, another light source capable of generating light of a single wavelength, such as a radiation beam, may also be used as the light source 100, but aspects of the present inventive concept are not limited thereto.

The light enhancer 200 is configured to receive and enhance the light emitted from the light source 100. The light enhancer 200 may include a first lens 210 and a second lens 220. In the light enhancer 200, the focus position of the first lens 210 and a second lens 220 may be adjusted to coincide with each other so as to convert narrow flux of parallel rays emitted from the light source 100 into thick flux of parallel rays. The first lens 210 may be an entrance lens and the second lens 220 may be an emission lens. A diameter (D) of the flux of the light enhanced by the optical enhancer 200 may be determined by the following equation: D/d=f2/f1, where d is a diameter of the flux of the incident light to the optical enhancer 200, f1 and f2 are the focal lengths of the first lens 210 and the second lens 220, respectively. The narrow collimated beam flux emitted from the light source 100 may be converted into the thick collimated beam flux. As shown in FIG. 1, the first lens 210 may be a concave lens and the second lens 220 may be a convex lens, but aspects of the present inventive concept are not limited thereto.

The first position adjusting unit 300 is configured to adjust a position of the second lens 220 to adjust a distance d1 between the first lens 210 and the second lens 220. The first position adjusting unit 300 may adjust a range in which the light is enhanced by adjusting the distance d1. The range in which the light is enhanced may affect the number of the multiple beams separated and focused through the lens array 400. For example, if the d1 between the first lens 210 and the second lens 220 is reduced, the range in which the light is enhanced may be reduced and the number of the multiple beams separated through the lens array 400 may also be reduced. However, if the d1 between the first lens 210 and the second lens 220 is increased, the range in which the light is enhanced may be increased and the number of the multiple beams separated through the lens array 400 may also be increased.

The lens array 400 is configured to separate the light enhanced by the light enhancer 200 into the multiple beams and focus the multiple beams. Since a plurality of lenses are arrayed in the lens array 400, the light enhanced by the light enhancer 200 can be separated into the multiple beams to then be focused. As shown in FIG. 1, the lens array 400 may be a convex lens array, but the invention is not limited thereto. In addition, the lens array 400 may be a liquid crystal micro lens array, but the invention is not limited thereto. The liquid crystal micro lens array may adjust focusing characteristics by adjusting a refraction index distribution in the liquid crystal layer using a patterned electrode structure or an uneven substrate surface structure. The lens array 400 may be a nematic liquid crystal micro lens array. In the nematic liquid crystal micro lens array, since phase matching conditions between a polymer thin film forming a concave lens and a liquid crystal layer forming a convex lens vary according to the voltage applied to the liquid crystal layer, the focal length can be continuously varied. The lens array 400 may be a ferroelectric liquid crystal micro lens array. In the ferroelectric liquid crystal micro lens array, a memory device capable of adjusting focusing characteristics while having bistability can be implemented using electro-optical properties of the ferroelectric liquid crystal. When a voltage is applied to the ferroelectric liquid crystal, the optical axis of the liquid crystal is rotated with respect to a polarization axis of incident light, thus electrically controlling focusing characteristics. The lens array 400 may include an anti-reflection (AR) coating 410.

The multiple beams separated through the lens array 400 reach the stage unit 500. A substrate 510 may exist on the stage unit 500 and patterns may be formed in the substrate 510 during exposure. The second position adjusting unit 600 may adjust a position of the stage unit 500. The stage unit 500 may include a piezoelectric (PZT) actuator. The PZT actuator converts electric energy into mechanical energy using a PZT ceramic. The stage unit 500 may include a stacked PZT actuator. The stacked piezoelectric actuator may generate the high conversion performance by stacking multiple disk layers. In the stacked piezoelectric actuator, each disk layer may be formed thin to reduce the operating voltage. A large electric field may be generated even with a low voltage by arranging electrodes in parallel in each disk layer. The PZT actuator may include a PZT element, which includes lead (Pb), zirconium (Zr), or titanium (Ti). For example, the PZT element may be PbO₃, ZrO₃, or TiO₃. The PZT does not undergo a volumetric change. Thus, if the PZT element extends in a longitudinal direction, it may shrink in a lateral direction. If the PZT element shrinks in a longitudinal direction, it may extend in a lateral direction.

Referring to FIG. 2, in a tailor-process based method for performing lithography, laser beams are focused into a quartz photomask 510a to generate a single shading element 10, and the stage unit 500 is then moved in a direction X1 to sequentially generate other shading elements 11 and 12. As described above, shading elements are generated all over the photomask 510a through a process of forming the shading elements one by one.

Referring to FIG. 3, the lithography apparatus according to an exemplary embodiment of the present inventive concept simultaneously forms a plurality of shading elements 20, 21, 22 and 23 on the photomask 510b through one-time exposure using the multiple beams. After forming the plurality of shading elements 20, 21, 22 and 23, the stage unit 500 is moved in a direction X2 to form a plurality of shading elements 30, 31, 32 and 33. Next, the stage unit 500 is moved in a direction X3 to form a plurality of shading elements 50, 51, 52 and 53. Next, the stage unit 500 is moved in a direction X4 to form a plurality of shading elements 40, 41, 42 and 43. Through the above-described repeatedly performed steps, the shading elements are formed all over the photomask 510b. The number of shading elements formed on the photomask 510b may be adjusted by adjusting the number and distance of movements of the stage unit 500. A pitch between the shading elements may be adjusted by adjusting the number of shading elements formed on the photomask 510b.

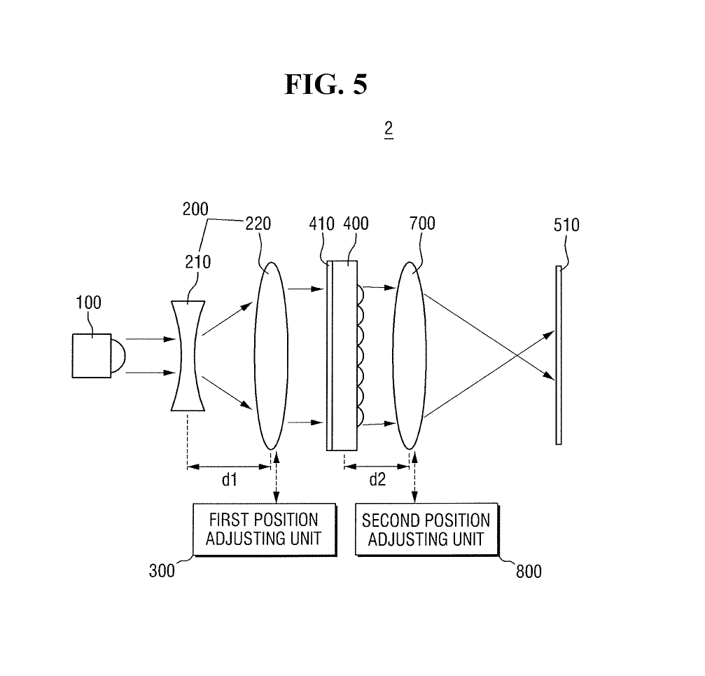

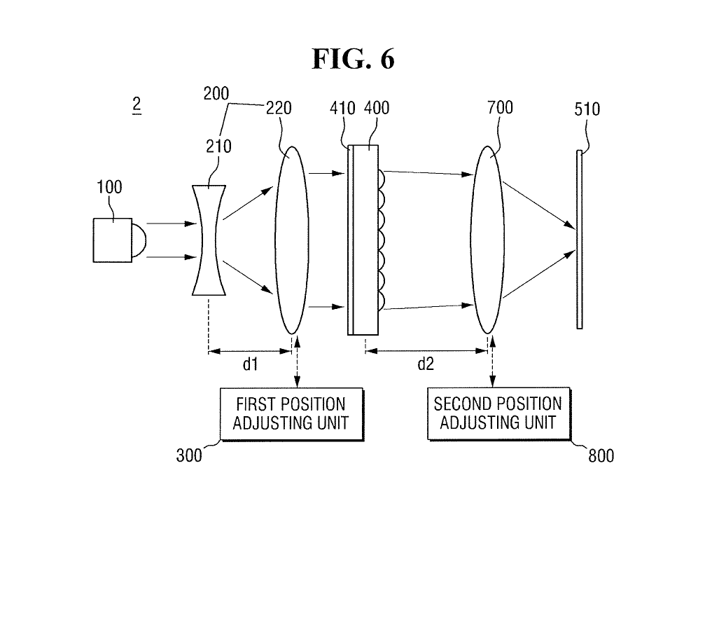

FIGS. 5 and 6 are partially exploded views of an apparatus for performing lithography according to an embodiment of the present inventive concept.

Referring to FIGS. 5 and 6, the lithography apparatus 2 according to an embodiment of the present inventive concept includes another light source 100, a light enhancer 200, a first position adjusting unit 300, a lens array 400, a projecting lens 700, and a third position adjusting unit 800.

The light source 100 emits light. The light source 100 may be a laser beam light source. In addition to the laser beam light source, a light source capable of generating a single wavelength, such as a radiation beam, may also be used as the light source 100, but aspects of the present inventive concept are not limited thereto.

The light enhancer 200 is configured to receive and enhance the light emitted from the light source 100. The light enhancer 200 may include a first lens 210 and a second lens 220. The first lens 210 may be an entrance lens and the second lens 220 may be an emission lens, but aspects of the present inventive concept are not limited thereto.

The first position adjusting unit 300 is configured to adjust a position of the second lens 220 to adjust a distance d1 between the first lens 210 and the second lens 220. The first position adjusting unit 300 may adjust a range in which the light is enhanced by adjusting the distance d1. The range in which the light is enhanced may affect the number of the multiple beams separated and focused through the lens array 400 may affect the number of the multiple beams separated and focused through the lens array 400.

The lens array 400 is configured to separate the light enhanced by the light enhancer 200 into the multiple beams and focus the multiple beams. Since a plurality of lenses are arrayed in the lens array 400, the light enhanced by the light enhancer 200 can be separated into the multiple beams that may be focused. As shown in FIGS. 4 and 5, the lens array 400 may be a convex lens array, but the lens array 400 is not limited thereto. In addition, the lens array 400 may be a liquid crystal micro lens array, but the lens array 400 is not limited thereto. The lens array 400 may include an AR coating 410.

The projecting lens 700 is configured to refract the multiple beams separated through the lens array 400. Referring to FIGS. 5 and 6, a range of the light reaching the substrate 510 may be adjusted by adjusting a distance d2 between the lens array 400 and the projecting lens 700. A pitch between the shading elements may be adjusted by adjusting the distance d2 between the lens array 400 and the projecting lens 700 while fixing the number of the multiple beams separated by the lens array 400. Referring to FIG. 5, if the distance d2 between the lens array 400 and the projecting lens 700 is reduced, a refraction extent of the plurality of refracted beams is increased, so that the pitch between the shading elements may be increased. Referring to FIG. 6, if the distance d2 between the lens array 400 and the projecting lens 700 is increased, a refraction extent of the plurality of refracted beams is reduced, so that the pitch between the shading elements may be reduced.

The third position adjusting unit 800 is configured to adjust a position of the projecting lens 700. A range in which the multiple beams are refracted may be adjusted by adjusting the distance d2 between the lens array 400 and the projecting lens 700. The pitch between the shading elements may be adjusted by adjusting the range in which the multiple beams are refracted.

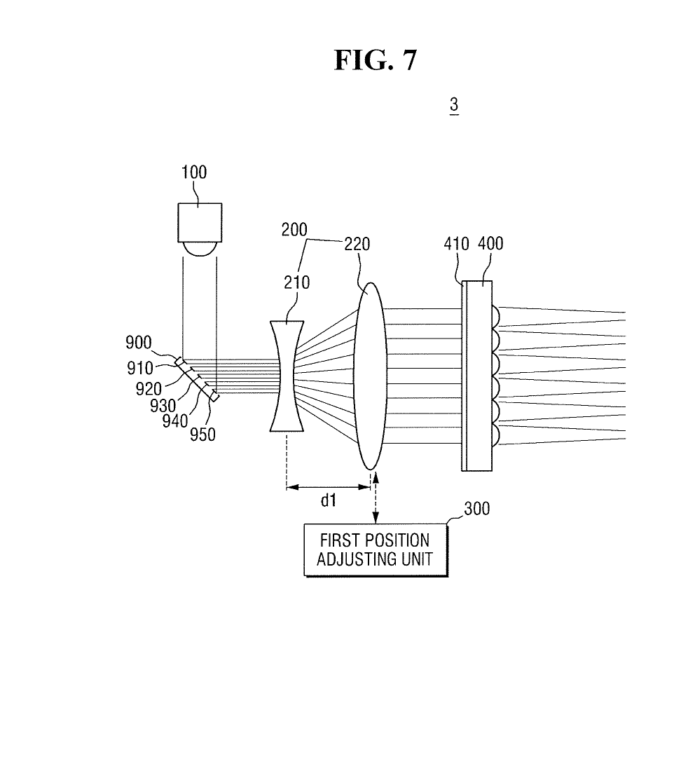

FIG. 7 is a partially exploded view of an apparatus for performing lithography according to an embodiment of the present inventive concept.

Referring to FIG. 7, the lithography apparatus 3 according to an embodiment of the present inventive concept includes a light source 100, a light enhancer 200, a first position adjusting unit 300, a lens array 400, and a spatial light modulator 900.

The light source 100 emits light. The light source 100 may be a laser beam light source. In addition to the laser beam light source, another light source capable of generating a single wavelength, such as a radiation beam, may also be used as the light source 100, but aspects of the present inventive concept are not limited thereto.

The light enhancer 200 is configured to receive and enhance the light emitted from the light source 100. The light enhancer 200 may include a first lens 210 and a second lens 220. The first lens 210 may be an entrance lens and the second lens 220 may be an emission lens, but aspects of the present inventive concept are not limited thereto.

The first position adjusting unit 300 is configured to adjust a position of the second lens 220 to adjust a distance d1 between the first lens 210 and the second lens 220.

The first position adjusting unit 300 may adjust a range in which the light is enhanced by adjusting a distance d1. The range in which the light is enhanced may affect the number of the multiple beams separated and focused through the lens array.

The lens array 400 is configured to separate the light enhanced by the light enhancer 200 into the multiple beams and focus the multiple beams. Since a plurality of lenses are arrayed in the lens array 400, the light enhanced by the light enhancer 200 may be separated into the multiple beams to then be focused. As shown in FIG. 7, the lens array 400 may be a convex lens array 400, but the lens array 400 is not limited thereto. In addition, the lens array 400 may be a liquid crystal micro lens array, but the lens array 400 is not limited thereto. The lens array 400 may include an AR coating 410.

The spatial light modulator 900 is configured to receive the light emitted by the light source 100, and reflect the light emitted by the light source 100 on portion 910, 920, 930, 940 and 950 of the spatial light modulator 900, while not reflecting the light emitted by the light source 100 on other portions of the spatial light modulator 900.

The spatial light modulator 900 modulates an input signal, e.g., a light signal or an electrical signal, into light using spatial pixels. The spatial light modulator 900 may be a grating light valve (GLV), a digital micromirror device (DMD), or a spatial optical modulator (SOM), but the spatial light modulator 900 is not limited thereto.

Referring to FIG. 7, a target pattern is formed on the substrate 510 (not shown in FIG. 7) using the spatial light modulator 900 and the target pattern is used in a multibeam-based lithography process.

In the case of using the lithography apparatus according to an embodiment of the present inventive concept, higher efficiency can be achieved, compared to the case of using the tailored lithography process (see Table 1).

TABLE 1

| | 1 Beam | | 5 × 5 Beams | |
|---|---|---|---|---|
| Laser power | 18 | mW | 450 | mW |
| Repetition rate | 50 | kHz | 50 | kHz |
| Exposure time and Settling time | 20 | μs | 20 | μs |
| Exposure pitch | 2 μm × 2 μm | | 10 μm × 10 μm | |
| Pattern X size | 96 | mm | 96 | mm |
| Pattern Y size | 136 | mm | 136 | mm |
| # of shots | 3264M | shots | 3264M | shots |
| Writing time | 65280 | s | 2611.2 | s |
| # of fields | 52224 | | 52224 | |
| Stage moving | 0.1 | s | 0.5 | s |
| Overhead time | 5222.4 | s | 26112 | s |
| Total time | 19.58 | hours | 2.17 | hours |

In the tailored lithography process, a total time of 19.58 hours may be taken in forming 2 μm×2 μm pitch shading elements over the entire area of a photomask. By contrast, in the lithography process according to an embodiment of the present inventive concept, for example, a total time of 2.17 hours may be taken in forming 10 μm×10 μm pitch shading elements over the entire area of a photomask using 5×5 beams. Therefore, according to an embodiment of the present inventive concept, the exposure time can be reduced.

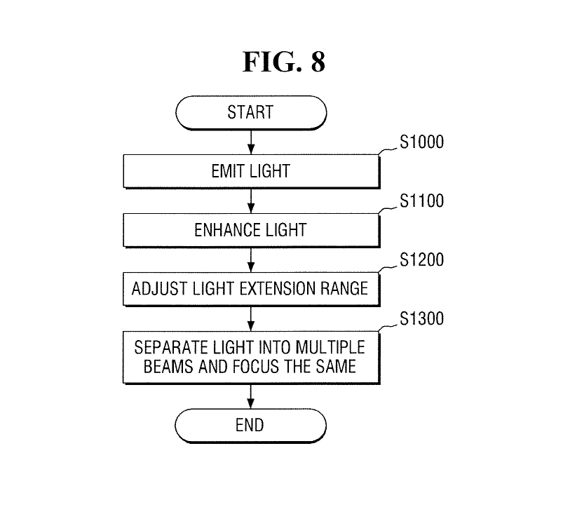

FIG. 8 is a flowchart illustrating a method for performing lithography according to an embodiment of the present inventive concept.

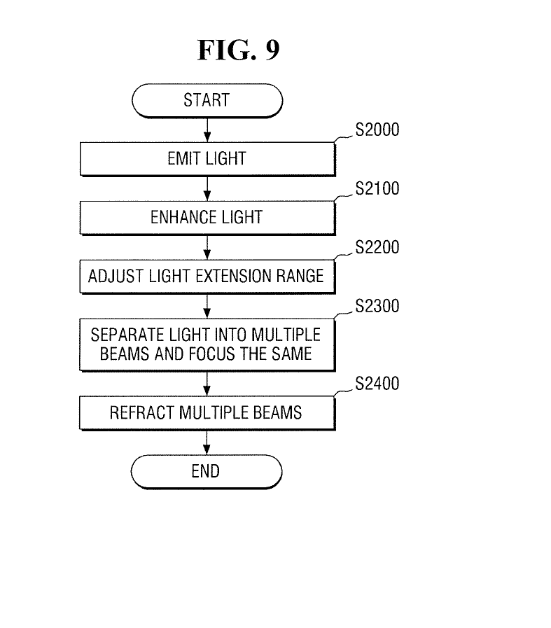

Referring to FIG. 8, a light is emitted (S 1000) and the emitted light is received and enhanced (S 1100). The light may be a laser beam. In addition to the laser beam light source, another light source capable of generating a single wavelength, such as a radiation beam, may also be used as the light source 100, but aspects of the present inventive concept are not limited thereto. A range in which the light is enhanced may be adjusted (S1200). The enhanced light is separated into multiple beams that may be focused (S1300). The number of multiple beams separated and focused may be adjusted. The number of multiple beams used during the lithography process may affect the number of shading elements formed through one-time exposure. FIG. 9 is a flowchart illustrating a method for performing lithography according to an embodiment of the present inventive concept. For the sake of convenient explanation, substantially the same details as those of the lithography method according to the previous embodiment may be omitted.

Referring to FIG. 9, a light is emitted (S2000) and the emitted light is received and enhanced (S2100). The light may be a laser beam. In addition to the laser beam light source, another light source capable of generating a single wavelength, such as a radiation beam, may also be used as the light source 100, but aspects of the present inventive concept are not limited thereto. A range in which the light is enhanced may be adjusted (S2200). The enhanced light is separated into multiple beams that may be focused (S2300). The number of multiple beams separated and focused may be adjusted. The number of multiple beams used during the lithography process may affect the number of shading elements formed through one-time exposure. The multiple beams are refracted (S2400). Before the separating and focusing of the enhanced light into the multiple beams (S2300), the multiple beams may be refracted (S2400) so as to adjust a pitch between shading elements formed on the photomask.

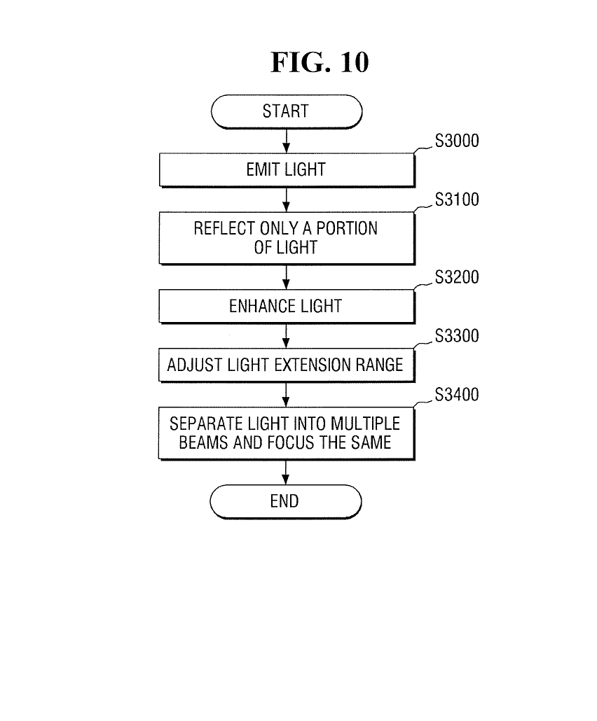

FIG. 10 is a flowchart illustrating a method for performing lithography according to an embodiment of the present inventive concept. For the sake of convenient explanation, substantially the same details as those of the lithography method according to the previous embodiment may be omitted.

Referring to FIG. 10, between emitting of light (S3000) and receiving and enhancing of the emitted light (S3200), the lithography method according to an embodiment of the present inventive concept may further include reflecting some portion of the light (S3100). For example, some portion of the emitted light may be reflected and the reflected light is received and enhanced using a spatial light modulator (S3200).

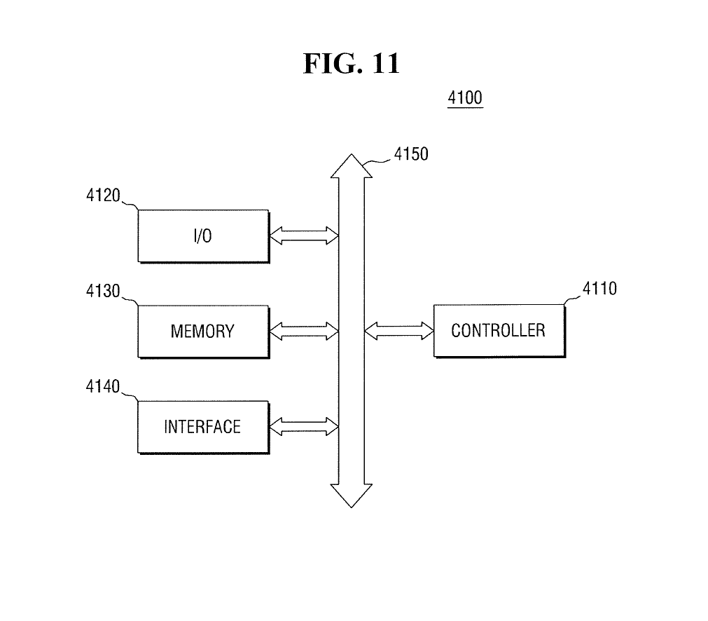

FIG. 11 is a block diagram of an electronic system including a semiconductor device fabricated using a lithography apparatus according to an embodiment of the present inventive concept.

Referring to FIG. 11, the electronic system 4100 may include a controller 4110, an input/output device (I/O) 4120, a memory device 4130, an interface 4140 and a bus 4150. The controller 4110, the I/O 4120, the memory device 4130, and/or the interface 4140 may be connected to each other through the bus 4150. The bus 4150 corresponds to a path through which data moves.

The controller 4110 may include at least one of a microprocessor, a digital signal processor, a microcontroller, or logic elements capable of functions similar to those of these elements. The I/O 4120 may include a key pad, a key board, a display device, or the like. The memory device 4130 may store data and/or codes. The interface 4140 may perform functions of transmitting data to a communication network or receiving data from the communication network. The interface 4140 may be wired or wireless. For example, the interface 4140 may include an antenna or a wired/wireless transceiver, and so on. Although not shown, the electronic system 4100 may further include high-speed DRAM and/or SRAM as the operating memory for improving the operation of the controller 4110. Fin type FETs according to embodiments of the present inventive concept may be incorporated into the memory device 4130 or provided as part of the I/O 4120.

The electronic system 1100 may be applied to a personal digital assistant (PDA), a portable computer, a tablet computer, a wireless land line phone, a mobile phone, a digital music player, a memory card, or any type of electronic device capable of transmitting and/or receiving information in a wireless environment.

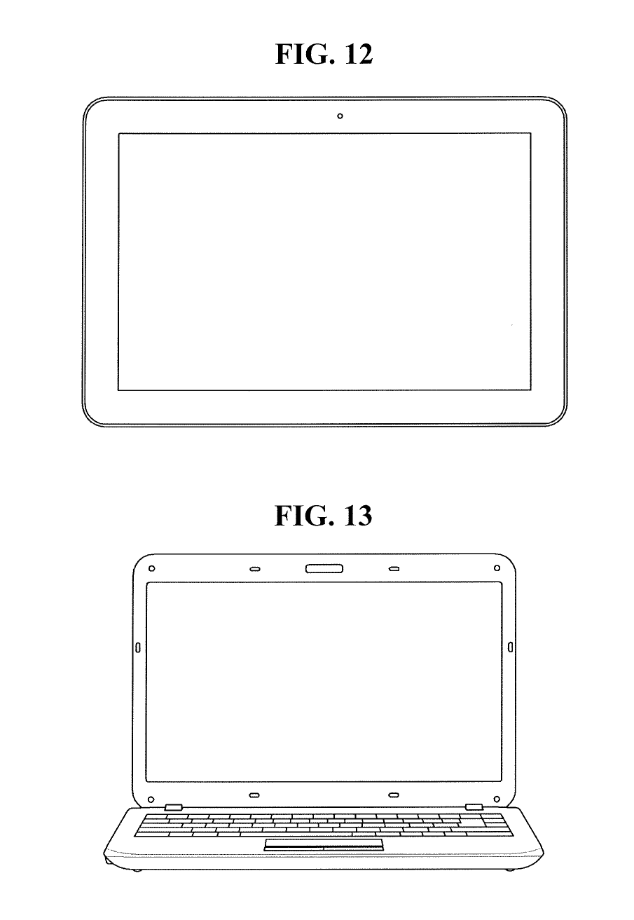

FIGS. 12 and 13 illustrate an exemplary semiconductor system to which semiconductor devices fabricated using a lithography apparatus according to an embodiment of the present inventive concept may be employed.

FIG. 12 illustrates an example in which a semiconductor device according to an embodiment of the present inventive concept is applied to a tablet PC, and FIG. 13 illustrates an example in which a semiconductor device according to an embodiment of the present inventive concept is applied to a notebook computer. At least one of the semiconductor devices fabricated using a lithography apparatus according to an embodiment of the present inventive concept may be employed to a tablet PC, a notebook computer, or the like. Semiconductor devices fabricated using a lithography apparatus according to an embodiment of the present inventive concept may also be applied to other IC devices not illustrated herein.

While the present inventive concept has been particularly shown and described with reference to exemplary embodiments thereof, it will be understood by those of ordinary skill in the art that various changes in form and details may be made therein without departing from the spirit and scope of the present inventive concept.

What is claimed is:

1. An apparatus for performing lithography comprising:
a light source emitting light;
a light enhancer configured to receive and enhance the emitted light, wherein the light enhancer includes a first lens and a second lens;
a first position adjusting unit configured to adjust a position of the second lens; and
a lens array configured to separate the light enhanced by the light enhancer into multiple beams, and focus the multiple beams.

2. The apparatus of claim 1, wherein the first lens is a concave lens, and the second lens is a convex lens.

3. The apparatus of claim 1, further comprising a stage unit configured to receive the multiple beams separated through the lens array.

4. The apparatus of claim 3, wherein the stage unit includes a PZT actuator.

5. The apparatus of claim 3, further comprising a second position adjusting unit configured to adjust a position of the stage unit.

6. The apparatus of claim 1, further comprising a projecting lens configured to refract the multiple beams separated through the lens array.

7. The apparatus of claim 6, further comprising a third position adjusting unit configured to adjust a position of the projecting lens.

8. The apparatus of claim 1, further comprising a spatial light modulator configured to reflect the light emitted by the light source on some portions of the spatial light modulator while not reflecting the light emitted by the light source on other portions of the spatial light modulator.

9. The apparatus of claim 8, wherein the spatial light modulator is one of a grating light valve (GLV), a digital micromirror device (DMD) or a spatial optical modulator (SOM).

10. The apparatus of claim 1, wherein the lens array includes an anti-reflection (AR) coating.

11. The apparatus of claim 1, wherein the light emitted from the light source includes a laser beam.

12. A method for performing lithography comprising:
emitting light;
enhancing the emitted light;
adjusting a range in which the light is enhanced;
separating the enhanced light into multiple beams; and focusing the multiple beams.

13. The method of claim 12, further comprising refracting the focused multiple beams.

14. The method of claim 12, further comprising reflecting some portion of the emitted light after the emitting of the light and before the enhancing of the emitted light.

15. The method of claim 12, wherein the emitted light is generated by a laser beam.

16. An apparatus comprising:
a light source;
a light enhancer configured to receive and enhance the light emitted by the light source,
a lens array configured to separate the light enhanced by the light enhancer into multiple beams and focus the multiple beams; and
a projection lens configured to refract the multiple beams separated through the lens array.

17. The apparatus of claim 16, wherein the light enhancer includes a first lens and a second lens.

18. The apparatus of claim 17, wherein the first lens is a concave lens, and the second lens is a convex lens.

19. The apparatus of claim 17, further comprising a position adjusting unit configured to adjust a position of the second lens.

20. The apparatus of claim 17, further comprising a position adjusting unit configured to adjust a position of the projection lens.
